(19) United States
(12) Patent Application Publication
(10) Pub. No.: US 2003/0102470 A1
(43) Pub. Date: Jun. 5, 2003

(54) Oxygen doping of josephson junctions

(76) Inventors: Evgeni Il'ichev, Jena (DE); Robbert P.J. IJsselsteijn, Jena (DE); Miles F.H. Steininger, Vancouver (CA)

Correspondence Address: Pennie & Edmonds, LLP, 3300 Hillview Avenue, Palo Alto, CA, 94304, US

(21) Appl. No.: 10/229,244

(22) Filed: Aug. 27, 2002

Related U.S. Application Data
(60) Provisional application No. 60/316,378, filed on Aug. 30, 2001.

(51) Int. Cl. H01L 29/06; H01L 31/0256; H01L 39/22

(52) U.S. Cl. 257/31

(57) ABSTRACT

A method of forming a grain boundary Josephson junction includes forming a superconducting layer on a substrate, patterning the superconducting layer to form the grain boundary Josephson junction, and annealing the substrate and superconducting layer in oxygen in order to increase the critical current density of the junction. The method is applicable to various types of junctions, including DD, DND, and SND junctions formed on various types of substrates, including bi-crystal substrates and single crystal substrates. The annealing is reversible. Oxygen can be removed from the junction, thereby decreasing the critical current density of the junction. In some instances, after patterning, the superconducting layer has a dimension smaller than a length of a facet in the superconducting layer.

### CROSS REFERENCE TO RELATED APPLICATIONS

This application claims priority from U.S. Provisional Patent Application No. 60/316,378, “Oxygen Doping of Grain Boundary Josephson Junctions,” filed on Aug. 30, 2001. U.S. Provisional Patent Application No. 60/316,378 is incorporated herein in its entirety by this reference.

### FIELD OF THE INVENTION

This invention relates to superconducting materials and Josephson junctions and, more particularly, to increasing the critical current through a Josephson junction.

### BACKGROUND

Superconductors, when cooled below a characteristic superconducting transition temperature, T_{c}, have the ability to transmit electric current without resistance. This quality makes superconductors suitable materials for use in several applications, including power transmission, magnetic levitation, medical imaging detection, communication, data storage, as well as computational applications.

A superconductor loses its superconducting property when the current density carried by the superconductor exceeds the critical current, I_{c}, of the superconductor. Each superconducting material has a characteristic critical current I_{c} above which the material ceases to have superconducting properties. In practice, this loss of superconductivity limits the current-carrying capacity of superconducting materials.

There is a need in the art for increases in the critical current of superconducting devices, such as grain boundary Josephson junctions (GBJJs) (e.g., Josephson junctions). As illustrated in FIG. 11a, a GBJJ 1102 is an interruption of the translational symmetry of a superconducting bulk material 1160 by a spacer 1162 along the direction of current flow 1140. In some instances, the length of spacer 1162, along the direction of current flow 1140, is on the order of the coherence length of the superconducting bulk material 1160. The coherence length is one of the characteristic lengths for the description of superconductors. Coherence length is related to the fact that the superconducting electron density cannot change quickly within a superconductor, and therefore there is a minimum length over which a given change can be made. Otherwise the superconducting state would be destroyed. For example, a transition from the superconducting state to a normal state will have a transition layer of finite thickness that is related to the coherence length. Coherence length is described in Tinkam, Introduction to Superconductivity, Robert E. Krieger Publishing Company, Inc., Malabar Fla. (1980), pages 6-8, 10, 28, 65-68, 74-86, and 112-113, which are hereby incorporated by reference.

In some instances, a GBJJ is simply the interface between two superconducting grains that have different crystallographic orientations. GBJJ 1152 (FIG. 11b) illustrates such a junction. In FIG. 11b, superconducting grain 1180-1 has a different crystallographic orientation than grain 1180-2. The interface between grain 1180-1 and 1180-2 is the grain boundary of the junction (1186, FIG. 11b).

GBJJs 1102 and 1152 are members of a broad class of junctions, including, but not limited to, Josephson junctions, weak links (e.g., grain boundaries), insulating gaps, tunnel junctions, and constrictions. In fact, GBJJs 1102 and 1152 include any device (e.g., junction) in which the amplitude of the Ginzburg Landau order parameter of the superconductor is diminished. The Ginzburg Landau theory is described in Chapter 9 of Ketterson and Song, Superconductivity, (Cambridge University Press, 1999), which is hereby incorporated by reference in its entirety.

GBJJs are used in many types of devices. The Josephson effect of certain GBJJs is used, for example, in superconducting quantum interference devices (SQUIDs). SQUIDs are used for measurement and creation of magnetic fields. See, for example, chapter one of Barone and Paternò, Physics and Applications of the Josephson Effect, John Wiley & Sons, New York (1982), which is incorporated herein by reference in its entirety. Superconducting effects, particularly phenomena related to Josephson junctions, has utility in quantum applications since the quantum behavior at the Josephson junction has macroscopically observable consequences. In particular, certain GBJJs exhibit the breaking of time reversal symmetry and are therefore suited for quantum computing because of the existence of doubly degenerate ground states of persistent current within such junctions. For example, the doubly degenerate ground states of a persistent clockwise current 1172 (FIG. 11a) and persistent counterclockwise current (not shown) in the vicinity of such junctions can be used to form the basis states of a qubit in a quantum computer.

One drawback with the use of known GBJJs in superconducting qubits is faceting. Faceting (e.g., a roughness in surface 1146 at boundary 1162 between superconductor 1160-1 and 1160-2, FIG. 11a) affects the electrical characteristics of GBJJs. In fact, when there is too much faceting, it is not possible to use the GBJJ in order to perform useful quantum computing calculations. Faceting arises from the methods used to manufacture GBJJs. That is, although faceting is undesirable, conventional manufacturing techniques produce faceted grain boundaries.

Known grain boundary Josephson junctions (GBJJs) (e.g., Josephson junctions) have several limiting factors that hinder the creation of a homogeneous junction. Among these limiting factors are geometric defects of the crystals (e.g., grains 1160-1 and 1160-2, FIG. 1a; grains 1180-1 and 1180-2, FIG. 11b). Another limiting factor includes faceting, which produces nonlinear grain boundaries in superconducting materials. In particular, faceting is characterized by irregular depressions and elevations at superconductor grain boundaries. A grain boundary is the intersection of two superconducting materials. The faceting of a GBJJ has been studied. See, for example, Mannhart et al, 1996, Phys. Rev. B 53, 14586-14593, which is incorporated herein by reference in its entirety. The presence of geometric defects and faceting in superconducting materials provides motivation to make grain boundary Josephson junctions smaller. Smaller grain boundary Josephson junctions are less likely to be affected by geometric defects in the superconducting crystals that form the junction or the faceting that occurs at grain boundary Josephson junctions. Unfortunately, the miniaturization of grain boundary Josephson junctions comes at a cost. Smaller grain boundary Josephson junctions have smaller, often immeasurable, critical currents. When the critical currents are too small, the grain boundary Josephson junction is of little value. Thus there is distinct need in the art to identify methods that will increase the current in very small grain boundary Josephson junctions so that the problems with crystal defects and faceting can be avoided, while at the same time, the junction has sufficient critical current to provide utility in devices such as supercomputing devices.

Materials used to make GBJJs include high temperature superconductors such as YBa₂Cu₃O₇₋ₓ. GBJJs made with YBa₂Cu₃O₇₋ₓ using known techniques typically have faceting features that are about 10 to about 100 nm in size. See Mannhart et al., 1996, Phys. Rev. Lett. 77, 2782, which is incorporated herein by reference in its entirety. Increasing the critical current of GBJJs would permit junctions to be formed that are smaller than the length of such a facet.

Methods have been proposed for increasing the current density of bulk superconducting materials. Oxygen doping of bulk high temperature superconductors has been studied and its empirical effect on transport is known. Less well understood are the effects of doping GBJJs. In one approach, designed to enhance grain-boundary critical current densities J_{c}, Hammerl et al. doped YBa₂Cu₃O₇₋ₓ/Y₁₋ₓCaₓBa₂Cu₃O_{7-δ} superlattices with calcium during the epitaxial growth of such junctions on SrTiO₃ bicrystal substrate. Hammerl et al, 2000, Nature 407, 162. Hammerl et al. showed that preferentially overdoping the YBa₂Cu₃O₇₋ₓ/Y₁₋ₓCaₓBa₂Cu₃O_{7-δ} grain boundary defined by the SrTiO₃ bicrystal substrate (FIG. 12), relative to the bulk grains themselves, yields values of J_{c} that far exceed previously published values.

Although the work of Hammerl et al. is promising, there are a number of drawbacks to this approach. One, the structures of Hammerl et al. have reduced weak link behavior or reduced Josephson effects at the grain boundary Josephson junction (e.g., junction 1186, in FIG. 12). This effect can be pronounced at maximum critical current levels, rendering the junction unsuitable for use in Josephson junction-based technology. A second drawback is that the Hammerl et al. junctions are heterostructures. Because of this, additional Josephson junctions (e.g. junction 96, FIG. 12) are introduced between layers of superconducting material. The additional Josephson junctions lead to inhomogeneity of phase on either side of the grain boundary Josephson junction, thereby degrading the usefulness of the junction. A third drawback with the Hammerl et al. approach is that it is not reversible. That is, the doping of the YBa₂Cu₃O₇₋ₓ with calcium is only possible as the GBJJ is formed. Therefore, using the Hammerl et al. approach, the critical current cannot be adjusted after the junction is fabricated. Adjustment of the critical current of the GBJJ is desirable in several applications that use GBJJs.

Given the above background, what is needed in the art are methods for increasing the critical current of GBJJs. This, in turn, would allow for the design of GBJJs that are smaller than the mean incidence of defects in the materials used to make such junctions. It would also allow for the design of GBJJs that are smaller than the facets that arise in the grain boundaries used to make such junctions. This, in turn, would minimize undesirable electrical effects in GBJJs. What are further needed in the art are methods for adjusting the critical current of GBJJs.

### SUMMARY

The present invention provides methods for increasing the critical current of GBJJs so that the current density carried by such junctions can be increased. The methods of the present invention are reversible. Therefore, the methods of the present invention can be used to adjust the critical current of GBJJs. One embodiment of the present invention provides a method of fabricating a GBJJ. The method includes forming a superconducting layer on a substrate and then patterning the superconducting layer, thereby forming the grain boundary Josephson junction on the substrate. The inventive method further provides an annealing step in which the grain boundary Josephson junction on the substrate is annealed in oxygen in order to increase the critical current of the junction. In some embodiments, the method further includes a step in which the grain boundary Josephson junction is heated to a temperature of about 80° C. to about 120° C.

In some embodiments, the GBJJ is annealed by exposing the GBJJ to O₂ plasma. In some embodiments, the pressure of the O₂ plasma during at least a portion of the annealing is about 0.2 mbar to about 0.6 mbar. In some embodiments, the GBJJ is exposed to O₂ plasma for at least fifteen minutes.

The inventive methods are applicable to various types of grain boundary Josephson junctions, including, but not limited to, a junction between two unconventional superconductors (also referred to as a DD junction), a junction between two unconventional superconductors separated by an intermediate material such as normal metal (also referred to as a DND junction), and a junction between a conventional superconductor and an unconventional superconductor separated by an intermediate metal such as a normal metal (also referred to as a SND junction). The methods of the present invention are applicable to junctions formed on various types of substrates, including bi-crystal substrates and single crystal substrates. Bicrystal substrates are those substrates that have a first portion having a first crystallographic orientation and a second portion having a second crystallographic orientation that is different from the first crystallographic orientation. A normal metal is any metal that is not in a superconducting state.

In some embodiments, after the patterning step, the superconducting layer has a dimension smaller than a length of a facet in the grain boundary in the substrate. In some embodiments, the grain boundary Josephson junction has a dimension between about 10 nm and about 100 nm. In some embodiments, the forming step comprises depositing a first superconducting material over a first portion of the substrate and depositing a second superconducting material over a second portion of the substrate. In some embodiments, the first portion of the substrate has a first crystallographic orientation and the first superconducting material adopts the first crystallographic orientation. Further, the second portion of the substrate has a second crystallographic orientation that is distinct from the first crystallographic orientation and the second superconducting material adopts the second crystallographic orientation.

In some embodiments, the superconducting layer comprises an unconventional superconducting material. In some embodiments, the superconducting material is a d-wave material such as YBa₂CuOₓ.

In some embodiments, the patterning step further comprises forming a space between a first portion of the superconducting layer and a second portion of the superconducting layer and depositing a material in the space that is not an unconventional superconductor. In some embodiments, the material that is deposited in the space is a non-superconducting metal, a semiconductor, or a dielectric material.

In some embodiments, the substrate is a single crystal substrate, and a seed layer is deposited on a portion of the substrate prior to forming the superconducting layer. In such embodiments, the seed layer has a crystallographic orientation that differs from the crystallographic orientation of the substrate.

In some embodiments, the annealing comprises contacting the grain boundary Josephson junction on the substrate with an O₂/N₂ gas mixture. In some embodiments, this O₂/N₂ gas mixture comprises about 800 mbar of N₂ and about 200 mbar of O₂. In some embodiments, in which the Josephson junction on the substrate is contacted with an O₂/N₂ gas mixture, the method further comprises heating the substrate and superconducting layer to a temperature of about 200° C.

Another aspect of the present invention provides an apparatus that includes a grain boundary Josephson junction. The grain boundary Josephson junction is manufactured by the method comprising (i) forming a superconducting layer on a substrate, (ii) patterning the superconducting layer thereby forming the grain boundary Josephson junction on the substrate, and (iii) annealing the grain boundary Josephson junction on the substrate in the presence of oxygen.

### BRIEF DESCRIPTION OF THE DRAWINGS

FIG. 1 illustrates a plan view of a substrate used in some embodiments of the present invention.

FIG. 2 illustrates a plan view of a typical cut in a substrate in accordance with some embodiments of the present invention.

FIG. 3 illustrates a plan view of a substrate having pieces adjacent to each other in accordance with some embodiments of the present invention.

FIG. 4 illustrates a plan view of two d-wave superconductors on adjoined substrate pieces with a junction between the superconductors in accordance with some embodiments of the present invention.

FIG. 5 illustrates an elevation view of a junction with a zero angle θ to the normal of the substrate, in accordance with some embodiments of the present invention.

FIG. 6 illustrates an elevation view of a junction aligned with a non-zero angle θ to the normal of the substrate, in accordance with some embodiments of the invention.

FIG. 7 illustrates a plan view of a junction that exhibits faceting.

FIG. 8 illustrates a plan view of a Josephson junction having a width that is smaller than the width of facets in the grain boundary in the underlying substrate in accordance with one embodiment of the present invention.

FIGS. 9a-9b illustrate plan views of a junction with a width that is larger than the facets of the junction.

FIG. 10a illustrates a method of increasing the critical current of a junction in accordance with one embodiment of the invention.

FIG. 10b illustrates a method of decreasing the critical current of a junction in accordance with one embodiment of the invention.

FIGS. 11a and 11b illustrate grain boundary Josephson junctions in accordance with the prior art.

FIG. 12 illustrates a YBa₂Cu₃O_{7-δ}/Y₁₋ₓCaₓBa₂Cu₃O_{7-δ} grain boundary Josephson junction defined by the SrTiO₃ bicrystal substrate in accordance with the prior art.

FIG. 13 illustrates a bicrystal dc SQUID that includes a Josephson junction 1302 at the grain boundary in accordance with the prior art.

Like reference numerals refer to the corresponding parts throughout the several views of the drawings.

### DETAILED DESCRIPTION

In accordance with embodiments of the invention, a GBJJ is fabricated, typically in a manner such as that described by Il'ichev et al., 1999, Phys. Rev. B 60, 3096, which is hereby incorporated by reference. Then, the GBJJ is doped with oxygen, thereby increasing the critical current of the junction. In some embodiments, increasing the critical current of a junction reduces the undesirable effects of faceting or crystal defects by permitting the fabrication of usable junctions that are smaller than the width of facets in the junction.

Embodiments of the present invention are broadly applicable in the general field of superconducting technology including the rapidly developing field of quantum computing. In particular, embodiments of the present invention may be useful for devices based on Josephson junctions where one side of the Josephson junction is comprised of a cuprate superconducting material or another material for which superconducting parameters are affected by oxygen content. Embodiments of such Josephson junctions are DND, SND, and DD junctions, where “D” is an unconventional superconductor; “S” is a conventional superconductor; and “N” is a type of barrier i.e. a normal (nonsuperconducting) conducting material. An embodiment of an unconventional superconductor is a d-wave superconductor such as a cuprate or copper-oxide superconductor, for instance, the known high temperature superconducting material YBa₂Cu₃O₇₋ₓ.

To better explain the terms “unconventional superconductor” and “conventional superconductor,” a brief review of the superconducting art is needed. Conventional superconductors are described by Bardeen, Cooper, and Schrieffer (“BCS”) theory, in which the superconducting electrons are paired in a zero net momentum and spin state by weak attractive interactions (weak-coupling superconductors) between the electrons. It is held that the attraction between the electrons is mediated via the lattice vibrations (that is, phonons). These pairs of electrons are referred to as Cooper pairs. The relative orbital angular momentum of the Cooper pair can have a value of zero (“s-wave”), one (“p-wave”), two (“d-wave”), and so forth. A short range interaction can only lead to s-wave pairing. This simplest situation (s-wave pairing) is found in conventional (s-wave) superconductors.

However, a few years after BCS theory was formulated, Kohn and Luttinger examined the possibility of generating a weak residual attraction out of the Coulomb repulsion between electrons. They found that this attraction could occur in principle, but only for higher angular momentum, when the electrons in the Cooper pairs are prevented from close encounters by the centrifugal barrier. In certain “heavy-fermion” materials, e.g., uranium containing materials, superconductivity may be p-wave in nature. The term “unconventional superconductor” includes all superconducting states with any deviation from the ordinary BCS type of pairing. That is, materials in which the relative orbital angular momentum has a value other than zero (e.g., p-wave, d-wave materials).

Examples of unconventional superconducting materials include, but are not limited to, heavy fermions (e.g., UPt₃ and URu₂Si₂), Sr₂RuO₄ and the high-T_{c} cuprates (e.g., YBa₂Cu₃O₇₋ₓ, La_{1.85}Ba_{0.15}CuO₄, Tl₂Ba₂CuO₆₊ₓ, and Hg_{0 8}Tl_{0 2}Ba₂Ca₂Cu₃O_{8 33}). YBa₂Cu₃O₇₋ₓ is also referred to as YBCO. Conventional superconducting materials include, but are not limited to, aluminum (T_{c} 1.175 K), niobium (T_{c} 9.25 K), and indium (T_{c} 3.4 K), where T_{c} is the transition temperature of the material. That is, for temperatures above T_{c}, the material is not superconducting while for temperatures below T_{c}, the material can be superconducting.

In some embodiments, the techniques of the present invention are applied to Josephson junctions other than the DND, SND, and DD junctions described above. Furthermore, embodiments of the present invention are equally applicable to superconducting quantum interference devices (SQUIDs), qubits, and other devices that make use of the Josephson effect.

### Methods of Manufacturing Grain Boundary Josephson Junctions in Accordance With the Present Invention

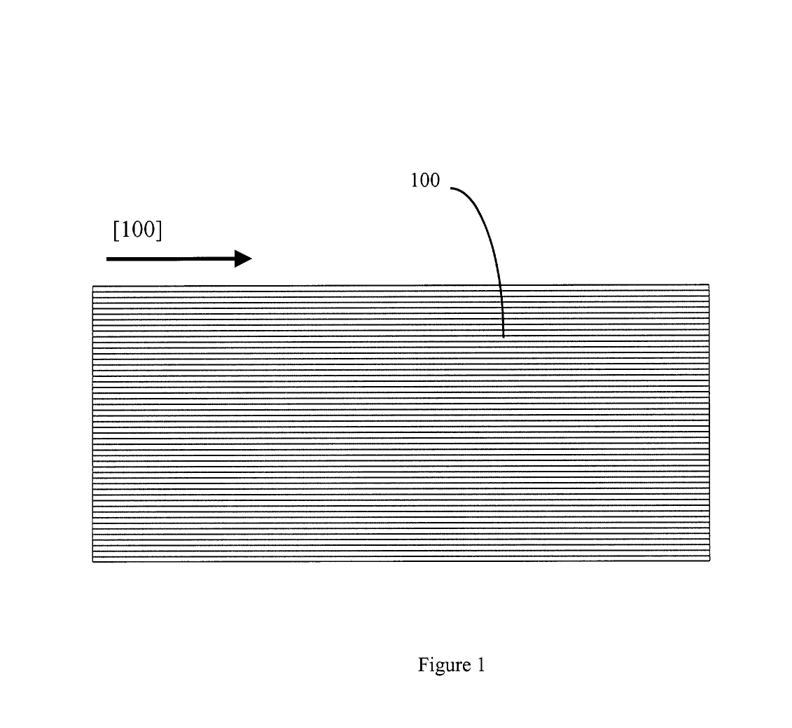

An example of oxygen doping of grain boundary Josephson junctions (GBJJs) in the superconductor YBCO will now be described in order to illustrate certain nonlimiting aspects of the present invention. Although fabrication and doping techniques are described for YBCO, the present invention has a much broader range of applicability beyond YBCO to other materials. FIGS. 1-4 describe a method of fabricating a Josephson junction on a bi-crystal substrate. Bi-crystals provide a reproducible way of creating grain boundaries suited for the deposition of superconducting material in order to form a grain boundary Josephson junction. Although a bi-crystal substrate is illustrated in FIGS. 1-4, the invention is equally applicable to junctions formed on single-crystal substrates. Single crystal methods include the biepitaxial techniques where seed layers are deposited on a portion of the substrate and patterned to form a grain boundary. See Nicolleti et al., 1999, Physica C 269, pp. 255-267, which is hereby incorporated by reference in its entirety. The fabrication method illustrated in FIGS. 1-4 involves depositing a first layer of superconducting material on a first portion of a substrate (e.g., a bicrystal substrate) and depositing a second layer of superconducting material on a second portion of the substrate. Then, the first and second layers are patterned to form a Josephson junction that includes a grain boundary. These steps are described in more detail below. In some embodiments, the grain boundary can be ballistic, meaning a normal metal separates the material on both sides of the junction. In some embodiments, the grain boundary is a tunneling boundary, meaning that an insulator separates the material on either side of the Josephson junction.

FIG. 1 depicts a plan view of a substrate 100. An example of a suitable substrate is SrTiO₃, however any other suitable substrate material may be used. Substrate 100 has the lattice vector labeled [100] or, alternatively, a, in FIGS. 1-10b.

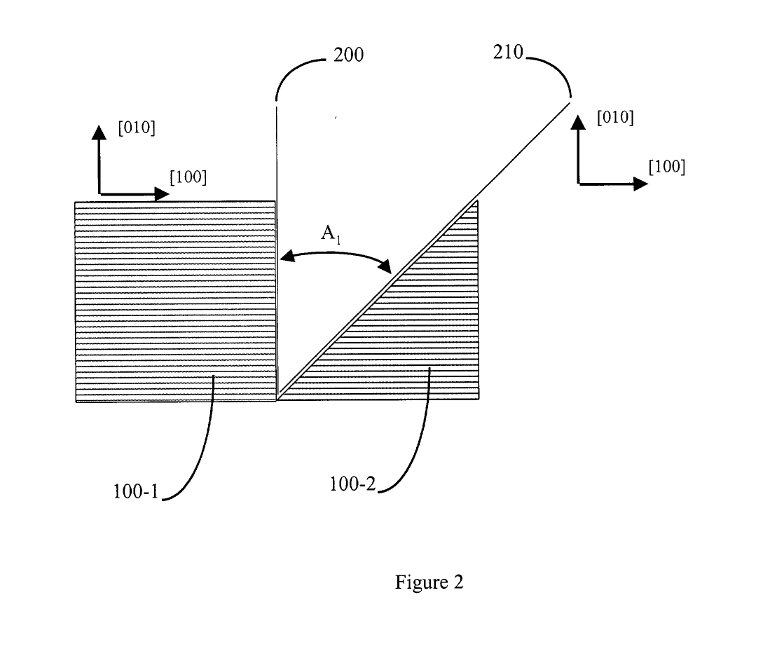

In FIG. 2, substrate 100 is cut into two pieces, 100-1 and 100-2. In practice, substrate 100 may be divided further. Pieces 100-1 and 100-2 are manipulated to make a bi-crystal boundary. For the particular example depicted in FIG. 2, the angle of the first cut 200 is perpendicular with respect to the grain of 100-1, and the angle of the second cut, 210, is not perpendicular to the grain of 100-1. The angle between cuts 200 and 210 may be, for example, 30 to 60 degrees. In one example, the angle of the cut is 45 degrees. The choice of angle is unrestricted. Further, cut 200 need not be perpendicular to the [100] direction. The cut geometry shown in FIG. 2 is one example of cuts used to form an asymmetric junction. A symmetric junction may be formed by making one cut at half of A₁ degrees and a second cut at minus half of A₁ degrees with respect to the grain.

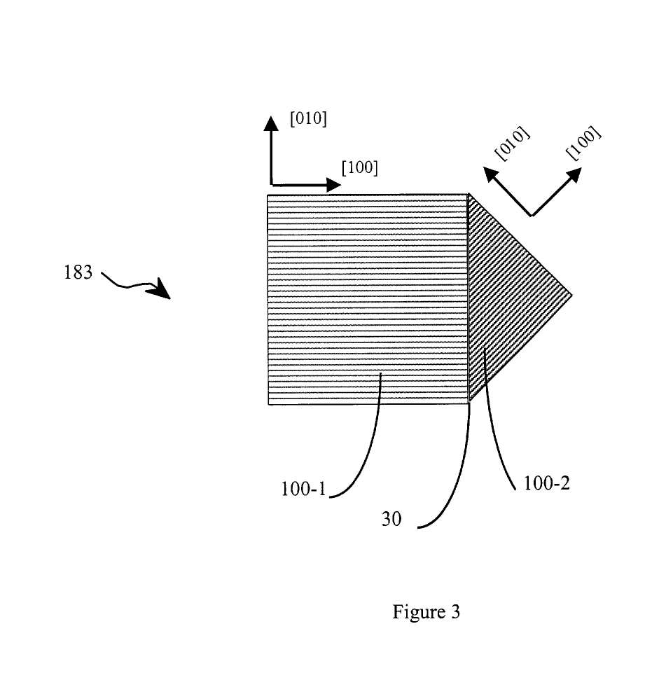

FIG. 3 depicts the rotation of piece 100-2 and its repositioning adjacent to piece 100-1. The angle of rotation is A₁, for example, 45 degrees. A grain boundary 30 between pieces 100-1 and 100-2 is the location where a grain boundary 30 is formed. The superconductor that is deposited above substrate 100 will have different orientations based upon the different lattice vector directions of pieces 100-1 and 100-2.

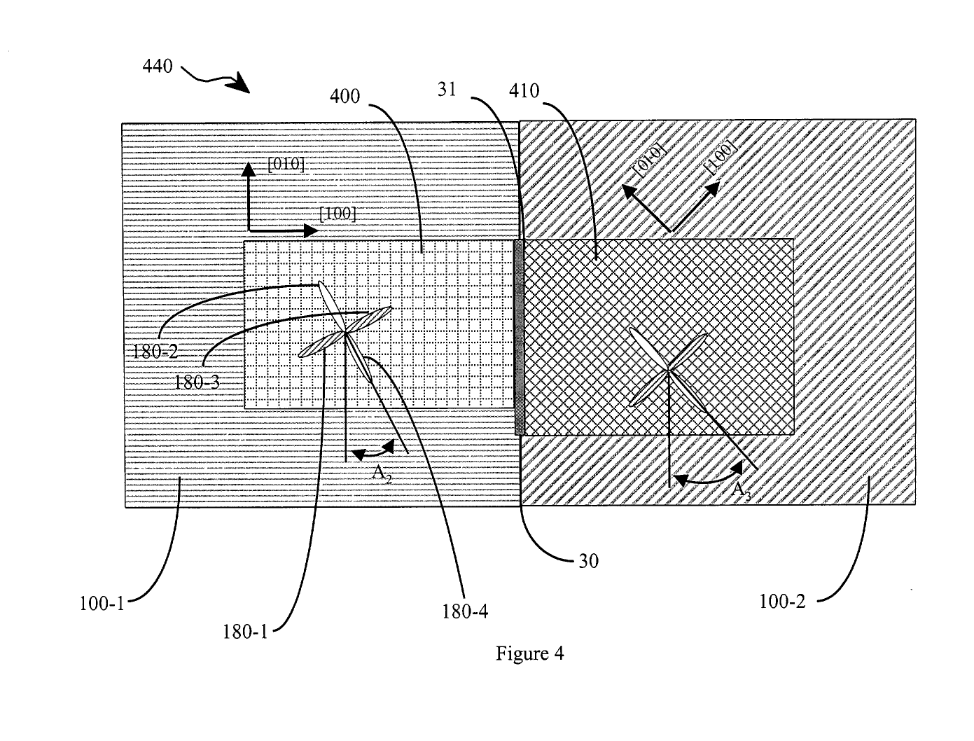

FIG. 4 depicts a portion of substrate 100-1 and 100-2 covered with a first and second superconducting material. In some embodiments, the first and second superconducting materials are deposited onto the substrate using pulsed laser deposition in order to form layers 400 and 410. That is, layer 400 is made of the first superconducting material and layer 410 is made of the second superconducting material. In some alternative embodiments, the superconducting material is deposited on the substrate by sputtering, thermal evaporation effusion (e.g., epitaxy), laser and thermal deposition, or another method, such as those disclosed in Van Zant, 2000, Microchip Fabrication, McGraw-Hill, which is hereby incorporated by reference.

Between the layers of superconducting material 400 and 410 is grain boundary Josephson junction 31. The particular Josephson junction 31 type (e.g. DD, DND, or SND) is application dependent. Embodiments of Josephson junction 31 include a DD junction where Josephson junction 31 is a grain boundary between superconducting layers 400 and 410. In such embodiments, Josephson junction 31 is the interface between layers 400 and 410. Such an embodiment is representative of a grain boundary Josephson junction in accordance with the present invention. In other embodiments (e.g., DND or SND junctions), additional material is introduced into the grain boundary Josephson junction 31. For example, normal (e.g. non superconducting) material may be added into junction 31. Accordingly, embodiments of grain boundary Josephson junction 31 exist where a layer of normal conducting metal (e.g., non superconducting metal) separates superconducting layers 400 and 410 at junction 31. In one example in which a layer of normal conducting metal separates superconducting layers 400 and 410, junction 31 includes 5-25 nm of gold (Au) in a ramp type junction. In the case of DND or SND junctions, the superconducting material on either side of the grain boundary Josephson junction 31 can be unconventional superconducting material or conventional superconducting material (e.g., DND or SND grain boundary Josephson junctions). DND or SND junctions in accordance with some embodiments of the present invention are formed using known techniques. See, for example, Komissinski etal., 2001, “Observation of the second harmonic in superconducting current-phase relation of Nb/Au/(001)YBa₂Cu₃Oₓ heterojunctions,” Los Alamos National Laboratory preprint cond-mat/0106559. Embodiments of the present invention exist where the grain boundary Josephson junction comprises an insulator, such as aluminum-oxide (Al₂O₃), or a semiconductor material, such as gallium-arsenide (GaAs) or silicon (Si).

The pulsed laser deposition of superconducting materials 400 and 410, in accordance with one embodiment of the present invention, will now be described. After mounting sample 183 (FIG. 3) on a heater, the sample and heater are placed inside a deposition chamber. The deposition chamber is evacuated to about 1×10⁻⁵ mbar. In some cases, this evacuation takes approximately 15 to 45 minutes. In one embodiment, this evacuation takes 30 minutes. One mbar is defined as 10⁻³ atmospheres. Then, the O₂ pressure in the deposition chamber is increased so that it is in the range of about 0.1 mbar to about 0.4 mbar and the sample 440 is heated. In one embodiment, the O₂ pressure in the deposition chamber is set to about 0.2 mbar and sample 183 (FIG. 3) is heated in accordance to the schedule found in Table 1 below:

TABLE 1
Temperature and O₂ pressure at various time intervals during warm-up

| | | | | |
|---|---|---|---|---|
| Time (±0.1 minutes) | 0 | 5 | 10 | 25 |
| Temperature (±5° C.) | 20 | 300 | 600 | 760 |
| Pressure (±0.01 mbar) | 0.2 | 0.2 | 0.2 | 0.2 |

Once sample 183 has reached a temperature of 760° C., layers 400 and 410 (FIG. 4) are deposited onto substrate 100 by pulsed laser deposition. Deposition of superconducting layers 400 and 410 takes about 10-15 minutes at the set temperature (760 ° C.) and oxygen pressure (0.2 mbar). The sample is then cooled. The oxygen pressure is increased to 500 mbar and the substrate is cooled down slowly to 250° C. in one hour. Afterwards, the heater is cooled down quickly to room temperature in about 15 minutes. In some embodiments, layers 400 and 410 (FIG. 4) are about 40 nm to about 200 nm thick. In one embodiment, layers 400 and 410 are 100 nm thick. In some embodiments, the final temperature in the warm-up is between about 700° C. and about 840° C. Accordingly, in some embodiments, deposition of the superconducting layers takes place at a temperature between about 700° C. and about 840° C. Although exact cooling temperatures and times have been provided, it will be appreciated that these temperatures and times can be varied and such variance is within the scope of the present invention. For example, rather than increasing the oxygen pressure to 500 mbar cooling the substrate down to 250° C. in one hour, the oxygen pressure can be increased to between about 300 mbar and 900 mbar and the substrate can be cooled down to a lower temperature, such as about 150° C. to about 350 ° C. over a time period of about thirty minutes to about twenty-four hours.

In some embodiments, the method of forming superconducting layer 400 and 410 on the substrate comprises depositing superconducting material 400 over a first portion of substrate 100 and then depositing superconducting material 410 over a second portion of substrate 100. In some embodiments, the first portion of the substrate has a first crystallographic orientation and superconducting layer 400 adopts this first crystallographic orientation. Further, the second portion of the substrate has a second crystallographic orientation that is different than the first crystallographic orientation and superconducting layer 410 adopts the second crystallographic orientation. In some embodiments, the substrate is a bicrystal layer and the first portion of the substrate is one of the two crystals in the bicrystal substrate.

Once layers 400 and 410 have been deposited, they are patterned. In some embodiments, this patterning is accomplished using an etching technique such as Ar ion-beam etching. In other embodiments, a method such as lithography, thermal deposition, laser deposition, or ion milling with anions or cations is used to pattern the superconducting layers. Lithography is the process of transferring a pattern from a mask to a substrate. This is done through a sequence of steps: (i) application of photoresist (such as polymethylmethacrylate “PMMA”) to the layer of material that is to be patterned, (ii) selective exposure with ultraviolet, x-ray, or electron beams through a mask, and (iii) developing which removes unexposed photoresist from the desired regions. Part of the material is protected by the photoresist and the resist is less susceptible to etching than the exposed material. Etching is often done with a plasma and is analogous to a chemical or “wet” etch. The etching removes the unprotected portions of material. The process can be repeated. The ZBA e-beam series from Leica Microsystems AG (Wetzlar, Germany), for example, provides a suitable lithographic system for use in some embodiments of the present invention.

In one embodiment, layers 400 and 410 are patterned using ion milling with anions or cations, using commercially available equipment. One such system is an Ar etching system produced by Sentech Instruments GmbH of Berlin, Germany. Photoresist masks are useful in some embodiments as they allow for precise placement of materials. Photo and electron lithography can be used to shape the masks.

Referring to FIG. 4, in some embodiments, superconductor layers 400 and 410 have an isotropic order parameter 180, the sign and magnitude of which varies with angle. In one embodiment, superconductor layer 400 has an isotropic order parameter 180 that is at angle A₂ to the junction. Further, superconductor layer 410 has a directional order parameter that is at an angle A₃ for layer 410. Order parameters are classified according to symmetry. An example of a material with an isotropic order parameter is YBCO. YBCO has d-wave symmetry. The lobes of the order parameter are oriented at an angle (e.g., A₂ and A₃ in FIG. 4) to a reference direction. In FIG. 4, the positive lobe 180-4 of the order parameter 180 of superconducting material 400 is at an angle A₂ with the principle direction of grain boundary 30 (FIG. 4). In FIG. 4, the order parameter of superconducting material 410 is at an angle A₃ with the principle direction of grain boundary 30. There are positive and negative lobes of a d-wave order parameter. The lobes are ninety degrees apart and both the negative lobes (e.g., 180-1, 180-3) are 180 degrees apart. Likewise, both the positive lobes (e.g., 180-2, 180-4) are 180 degrees apart. For a discussion of order parameter symmetry in copper oxide superconductors see Tsuei and Kirtley, 2000, Reviews of Modern Physics 72, 969, which is hereby incorporated by reference in its entirety.

In some embodiments, patterned layers 400 and 410 have the same dimensions, including height, width, and length. In other embodiments, at least one of the height, width, and length of patterned layers 400 and 410 is different. In some embodiments, layer 400 is deposited and/or patterned in a method that is different from that of layer 410. In some embodiments, layers 400 and 410 are made of the same material. In other embodiments, layers 400 and 410 are made of a different material. After deposition, the Josephson junction device may be structured using electron beam-lithography.

Another method for fabricating a grain boundary Josephson junction in accordance with the present invention includes the bi-epitaxial formation of a grain boundary. In such embodiments, a substrate with a single crystallographic orientation is used and the substrate is not cut as illustrated in FIGS. 2 and 3. Rather, a seed layer is deposited on a portion of the substrate. The seed layer has a different crystallographic orientation than the substrate. Accordingly, the partially covered substrate presents two crystallographic orientations, the portion of the uncovered substrate and the portion of the substrate that is covered by a seed layer. In another bi-epitaxial method, two seed layers are used. One seed layer is used to cover a first portion of the substrate and another seed layer is used to cover a second portion of the substrate. The two seed layers have different crystallographic orientations. In this way, the substrate, in combination with one or more seed layers, presents two different crystallographic orientations across a grain boundary. Superconducting material deposited on these surfaces will adopt the crystallographic orientation of the underlying surface (e.g., exposed substrate or seed layer). The seed materials MgO and CeO₂, can be used, for example, to generate a 45 degree asymmetric grain boundary.

### Junctions in Accordance With the Present Invention

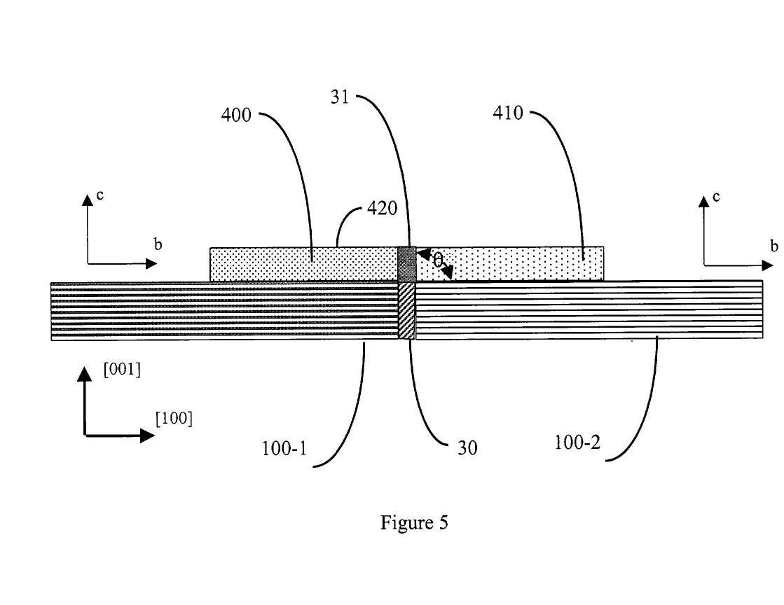

FIG. 5 is an elevation view of the junction shown in FIG. 4. Grain boundary 30 divides superconductor layer 400 and 410, and substrate portions 100-1 and 100-2. The Josephson junction 31 exists at that portion of grain boundary 30 that lies between superconductor layers 400 and 410. In the embodiment illustrated in FIG. 5, the angle θ that the Josephson junction makes with the normal to the surface of layer 400 (surface 420) is zero. The Josephson junction can be microscopic, or it can be a mesoscopic etch that partially separates the superconductors. Junctions incorporating embodiments of the invention can be clean, meaning no intermediate layer separates superconductors 400 and 410, or dirty, meaning that an intermediate layer, such as normal (nonsuperconducting) metal or insulator, separates superconductors 400 and 410. The Josephson effect is present in all weak links, thus embodiments of the invention are not limited to the grain boundary illustrated in FIG. 5.

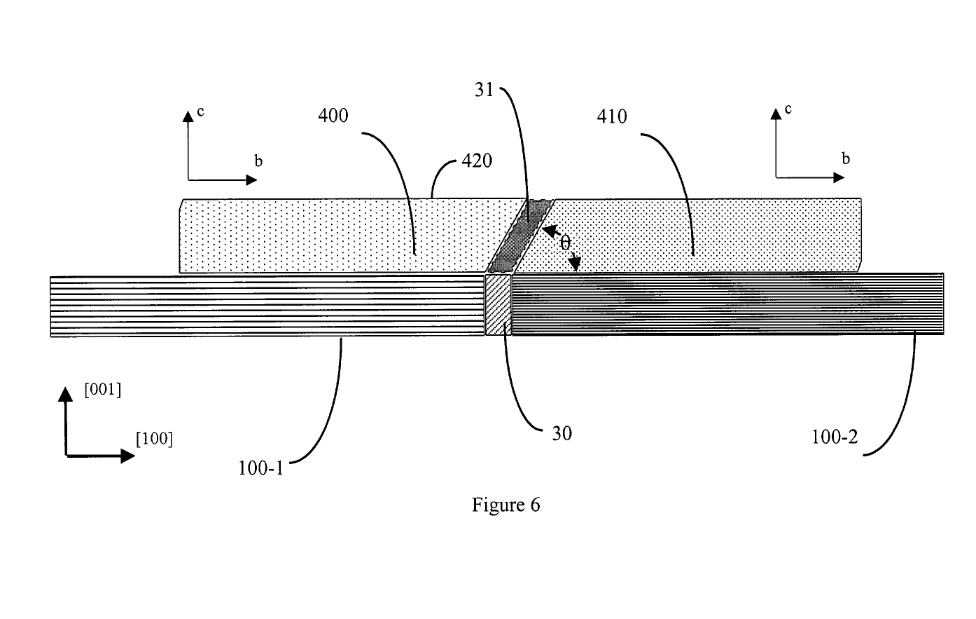

FIG. 6 is an elevation view of another geometry of a grain boundary 30 and grain boundary Josephson junction 31. Grain boundary 30 resides between substrate portions 100-1 and 100-2 and grain boundary Josephson junction 31 resides between layers 400 and 410. The angle θ of the junction (the portion of boundary 30, regions 31, that separates layers 400 and 410) with the normal to the surface of layer 400 (surface 420) is non-zero for the example depicted in FIG. 6. The angled boundary provides a degree of freedom in selecting a configuration that provides the desired phase difference in the superconducting order parameters of layers 400 and 410.

### Faceting

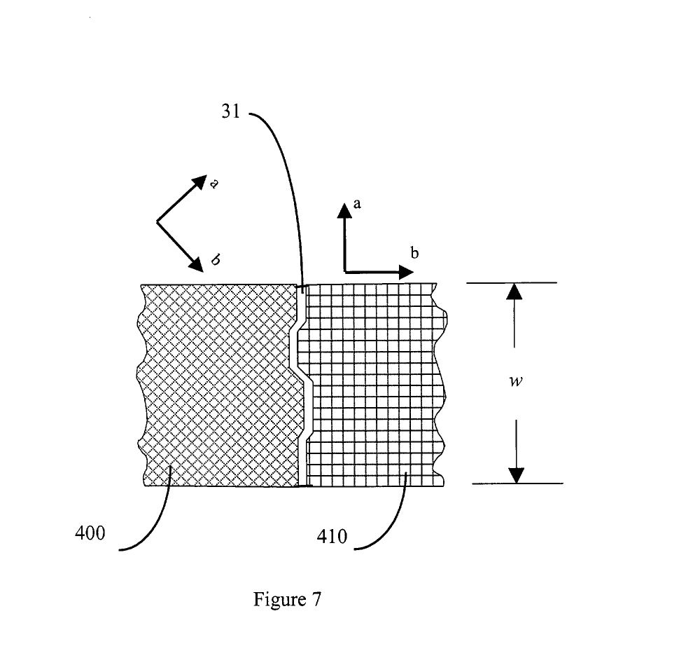

The interface between layers 400 and 410 across grain boundary 30 is typically not smooth. Rather, it is faceted. This leads to the undesirable electronic effects discussed above. In order to avoid the undesirable electronic effects of faceting, the width w (FIG. 7) of the junction is reduced to less than the length of a single facet in accordance with one embodiment of the present invention.

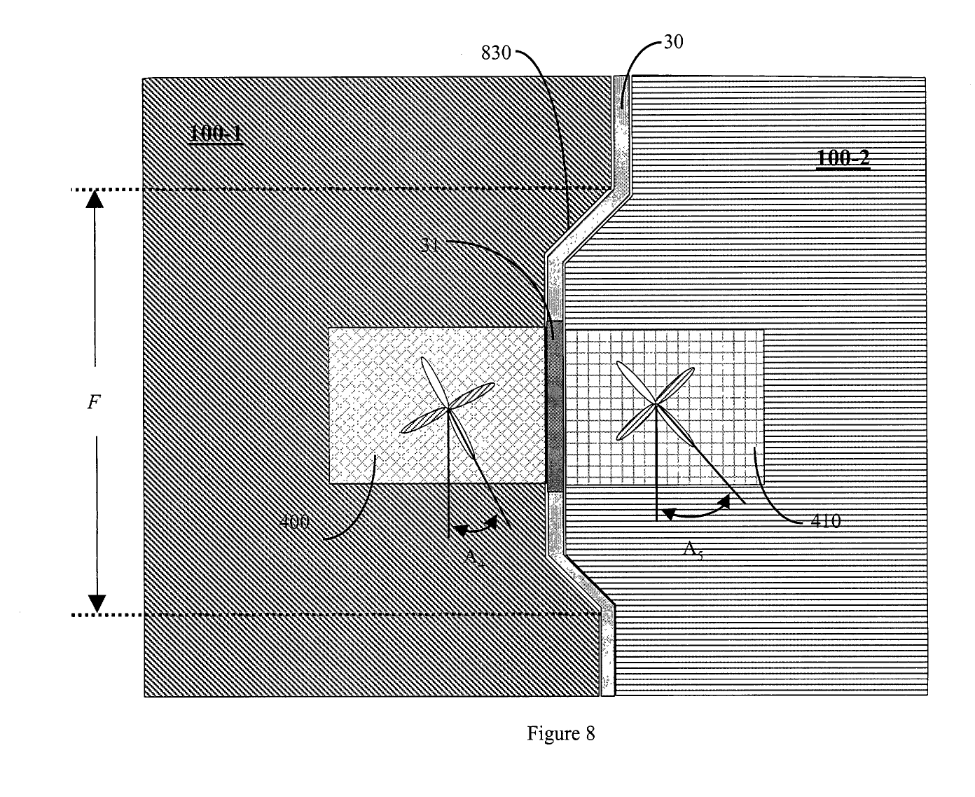

FIG. 8 shows a facet 830 that is found within substrate 100 at grain boundary 30. FIG. 8 further depicts a Josephson junction 31 that has a width that is less than the width F (FIG. 8) of facet 830. In FIG. 8, Josephson junction 31 is that portion of grain boundary 30 (FIGS. 4-6) that contacts superconducting layers 400 and 410. In some embodiments, the width of Josephson junction 31 is 5 microns or less. In some embodiments, the width of Josephson junction 31 is 2 microns or less. In some embodiments, the width of Josephson junction 31 is 0.5 microns or less. In yet other embodiments, the width of Josephson junction 31 is 250 nanometers or less. In the illustrated embodiment, Josephson junction 31 is straight. However, in other embodiments, Josephson junction 31 is angled, for example, as illustrated by Josephson junction 31 in FIG. 6, which illustratively adopts an angle θ that is other than ninety degrees. In embodiments where the width of Josephson junction 31 is less than the width F of facet 830, the contact area of junction 31 (e.g., the total surface area of junction 31 that contacts layer 400 and/or layer 410) is greatly diminished relative to junctions 31 (not shown) that are wider than the width F of facet 830. Josephson junctions 31 that are less than the width F of a facet 830 are desirable because their electrical properties are not adversely affected by faceting. However, the reduced contact area of Josephson junctions 31 having a width that is less than the width F of a facet 830 presents a problem in some instances. For example, in the case of a sub-micron junction 31, where layers 400 and 410 are 100 nanometer thick film of YBCO, the critical current is reduced to a level that is difficult to measure with known measuring equipment when the width of the junction is less than 1 micron. The methods of the present invention address this problem by treating junctions 31 in order to increase their critical current, as discussed in the next section.

In some embodiments of the present invention, layers 400 and 410 are YBCO film. Defects in YBCO layers occur at approximately one micron intervals along a grain boundary. The defects are often due to imperfections in the substrate 100 below the YBCO layer. However, such defects can originate in the YBCO layer (e.g., layers 400, 410) itself. To form a Josephson junction 31 in a YBCO layer that is not affected by the defects of the YBCO necessitates the formation of a submicron GBJJ (e.g., a GBJJ that has a width that is less than about 1 micron).

In addition to defects, high temperature superconductors, such as YBCO, typically have faceting. This faceting is on the scale of 10-100 nm, see Mannhart et al., 1996, Phys. Rev. Lett. 77, 2782, which is incorporated herein by reference in its entirety. Faceting has an undesirable affect on the phase difference of a Josephson junction that includes a facet. One approach to reducing the faceting effect on the phase difference in a Josephson junction is to create a grain boundary Josephson junction that has a width that is on the same scale as the feature width of a facet in accordance with the methods of the present invention. In the case of YBCO, the GBJJ has a width of about 10-100 nm in such embodiments. The boundary in such junctions tends to be uniform and the difference in order parameters at such junctions (e.g., junction 31 in FIG. 8) approaches theoretical expectations because of the simple geometry of the junction. However, due to the reduction injunction size, there is less volume for current to pass through. Since there must be a sufficiently large critical current for the GBJJ to function, the critical current of the junction must be increased.

### Increasing the Critical Current of Grain Boundary Josephson Junctions

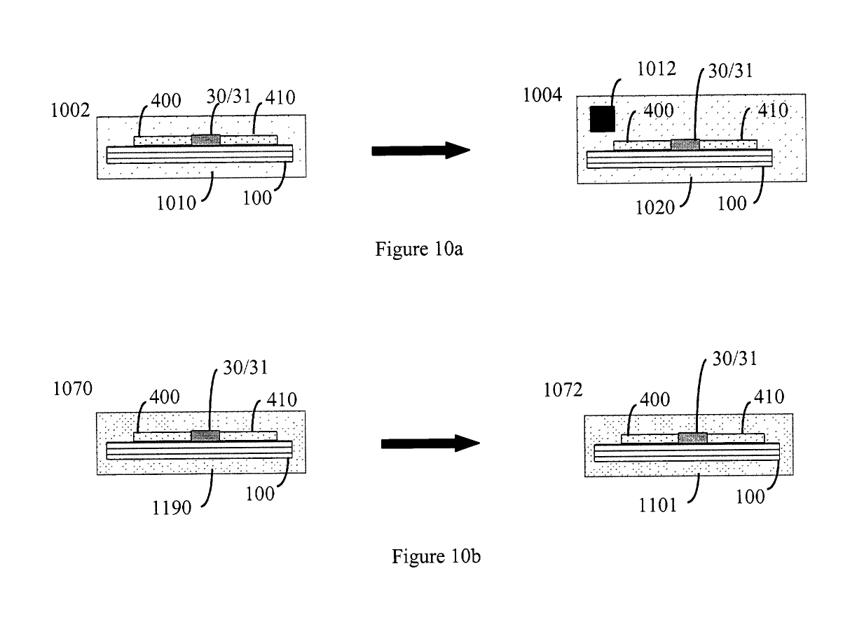

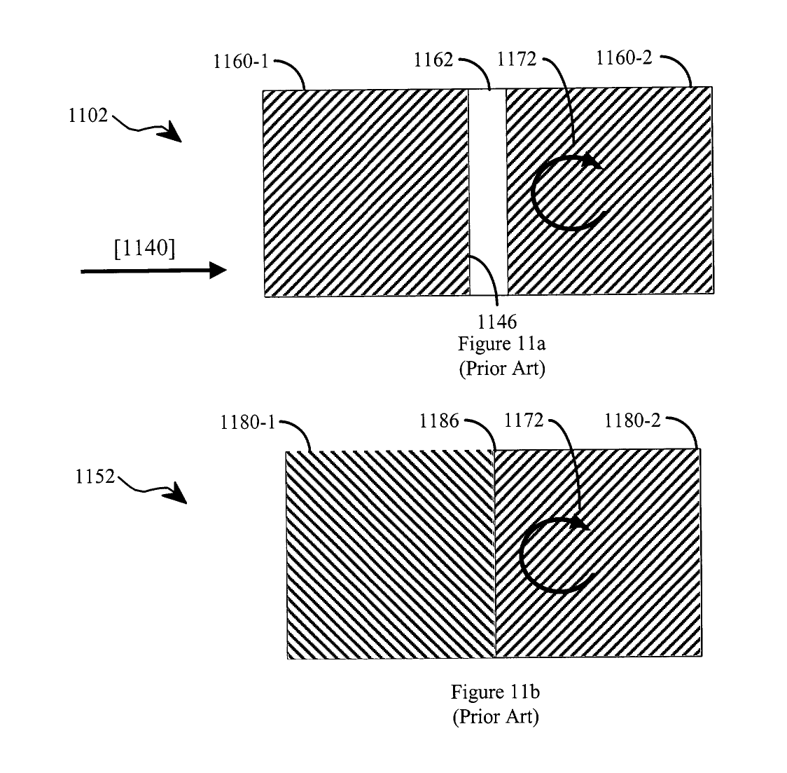

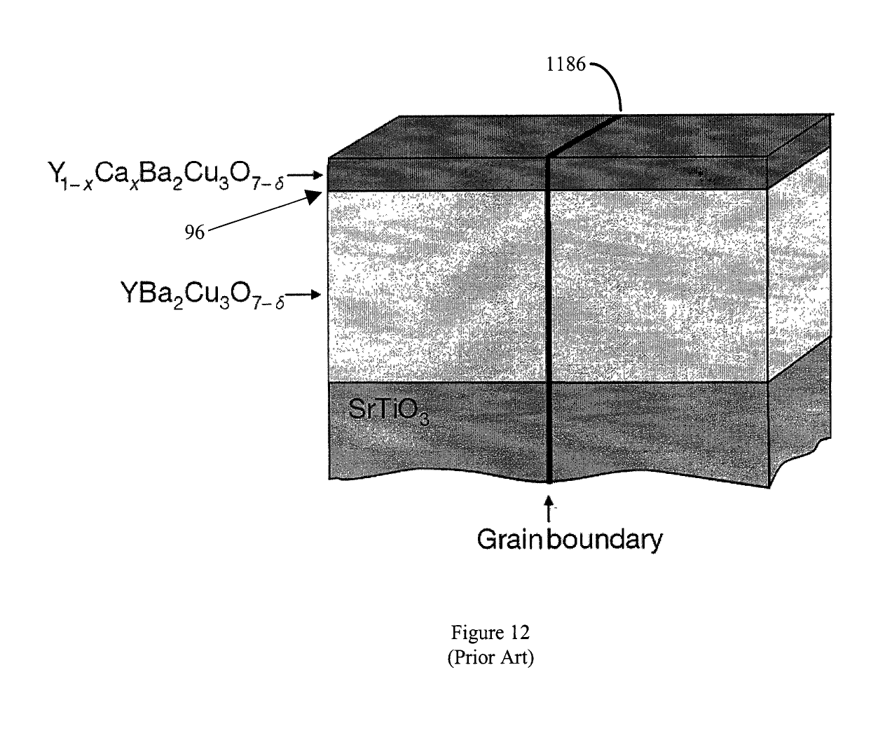

FIG. 10a illustrates a method of increasing the critical current of a grain boundary Josephson junction 31 in accordance with one embodiment of the present invention. The method illustrated in FIG. 10a is used to increase the critical current of any of the junctions shown in FIGS. 4-8 and 9a-9b, as well as many other types of grain boundary Josephson junctions that are not described by these figures. In step 1002 (FIG. 10a) of the inventive method, the structure that includes a grain boundary Josephson junction (e.g., FIG. 4, 440) is placed in an oxygen environment 1010. In one embodiment, step 1002 comprises contacting the structure (e.g., FIG. 4, 440) with oxygen at a pressure of about 0.4 mbar for about thirty minutes. In some embodiments, step 1002 comprises contacting the structure (e.g., FIG. 4, 440) with oxygen at a pressure of about 0.2 mbar to about 0.6 mbar for about fifteen minutes to about forty-five minutes. In some embodiments, step 1002 comprises contacting the structure (e.g., FIG. 4, 440) with oxygen at a pressure of about 0.1 mbar to about 0.8 mbar for about five minutes to about three hours. In some embodiments, step 1002 comprises contacting the structure (e.g., FIG. 4, 440) with oxygen at a pressure of about 0.1 mbar to about 5 mbar for at least five minutes. In one embodiment the O₂ gas is Medipure™ U.S.P. grade O₂ from PraxAir Technology, Inc.

In step 1004 (FIG. 10a), a high frequency electromagnetic source 1012 is activated to create plasma 1020 from oxygen environment 1010. Plasma generators are known in the art and include ionizing radiation generators, electron beam source, and other devices. The structure (e.g., FIG. 4, 440) is annealed and heated by plasma 1020. In some embodiments, high frequency electromagnetic source 1012 heats the structure (e.g., FIG. 4, 440) to 100° C. In some embodiments, high frequency electromagnetic source 1012 heats the structure (e.g., FIG. 4, 440) to at least 90° C. In some embodiments, high frequency electromagnetic source 1012 heats the structure (e.g., FIG. 4, 440) to about 80° C. to about 120° C.

FIG. 10b illustrates a method of decreasing the critical current of a Josephson junction 31 in accordance with one embodiment of the present invention. The method illustrated in FIG. 10b can be used to decrease the critical current of any of the junctions shown in FIGS. 4-8 and 9a-9b, as well as many other junctions that are not disclosed by these figures. In step 1070, the structure (e.g., FIG. 4, 440) is placed in a nitrogen and oxygen environment 1190. The structure is then heated in step 1072 until the desired reduction in critical current is achieved. In one embodiment, the structure (e.g., FIG. 4, 440) is heated to 200° C. in an environment of 800 mbar N₂ plus 200 mbar O₂ for 30 minutes during step 1072 to reduce oxygen content. In some embodiments, the structure (e.g., FIG. 4, 440) is heated to a temperature of about 160° C. to about 240° C. during step 1072. In some embodiments, environment 1190 comprises a mixture having about 500 mbar N₂ to about 1100 mbar N₂ and 100 mbar O₂ to about 400 mbar O₂. In some embodiments, the duration of the heating in step 1072 is about 10 minutes to about 60 minutes. In some embodiments, step 1072 reduces the critical current of Josephson junction 31 by a factor of two or three. In some embodiments, steps 1070 and 1072 are repeated. In fact, combinations of the steps of FIG. 10a (steps 1002 and 1004) and the steps of FIG. 10b (steps 1070 and 1072) may be performed in any order so that the oxygen content of superconducting layers 400 and 410 is regulated. In some embodiments, the N₂ gas is Medipure™ U.S.P. grade N₂ gas, semiconductor process gas grade 4.8, or semiconductor process gas grade 5.5.

In one embodiment of the present invention, a junction similar to the junction shown in FIG. 8 is used as the first of two junctions in a two-junction rf SQUID. This first junction has a submicron width. The second junction in the rfSQUID has a width on the order of millimeters. Prior to annealing in oxygen in accordance with the method illustrated in FIG. 10a, the critical current observed in the first junction is not capable of accurate measurement using known measuring devices. After annealing using the method illustrated in FIG. 10a, the critical current density increased to approximately 1 kA/cm² at 25 K. The improvement in critical current density, and therefore critical current, is a function of concentration of oxygen, exposure time and other factors. In some embodiments of the invention layers 400 and 410 are YBa₂Cu₃Oₓ and the oxygen content (x) of the YBa₂Cu₃Oₓ is a value between 6 and 7. Reproducibly, oxygen doping of grain boundaries improves the critical current of junctions 31. Further, the increase in critical current of such junctions 31 is reversible, using the methods of the present invention (e.g., the method illustrated in FIG. 10b).

Use of Junctions of the Present Invention as Qubits

Increased critical currents allow for the study of the current as a function of phase across the junction using a modified Rifkin-Deaver method, for example. See Rifkin and Deaver, 1976, Phys. Rev. B 13, 3894; and Il'ichev et al, 2001, Rev. Sci. Instr. 72, pp. 1882-1887, each of which is hereby incorporated by reference. A significant deviation in the current-phase relationship from a sinusoidal dependency for a typical junction towards a Kulik-Omelyanchuk behavior was observed in junctions fabricated in accordance with the methods of the present invention. This is a direct observation of second order current mode across the junction. This current mode allows junctions 31 to be used as part of a qubit.

A qubit is a quantum bit, the counterpart in quantum computing to the binary digit or bit of classical computing. Just as a bit is the basic unit of information in a classical computer, a qubit is the basic unit of information in a quantum computer. A qubit is conventionally a system having two degenerate (e.g., of equal energy) quantum states, wherein the quantum state of the qubit can be in a superposition of the two degenerate states. The two degenerate states are also referred to as basis states. Further, the two degenerate or basis states are denoted |0> and |1>. The qubit can be in any superposition of these two degenerate states, making it fundamentally different from a bit in an ordinary digital computer. If certain conditions are satisfied, N qubits can define an initial state that is a combination of 2^{N} classical states. This initial state undergoes an evolution, governed by the interactions that the qubits have among themselves and with external influences, providing quantum mechanical operations that have no analogy with classical computing. The evolution of the states of N qubits defines a calculation or, in effect, 2^{N} simultaneous classical calculations (e.g., conventional calculations as in those performed using a conventional computer). Reading out the states of the qubits after evolution completely determines the results of the calculations. Several physical systems have been proposed for the qubits in a quantum computer. One system uses molecules having degenerate nuclear-spin states. See Gershenfeld and Chuang, U.S. Pat. No. 5,917,322, which is herein incorporated by reference in its entirety. The Josephson junctions of the present invention can be incorporated into structures that are a new, novel, form of a qubit. Such structures include the permanent readout superconducting qubit and the superconducting low impedance qubit, each used by way of illustration and not limitation. See U.S. application Ser. No. 09/452,749 entitled “Permanent Readout Superconducting Qubit,” filed Dec. 1, 1999 and application Serial No. 60/316,134 entitled “Superconducting Low Impedance Qubit,” filed Aug. 29, 2001, each of which is hereby incorporated by reference in its entirety.

### Step-Like Embodiments of the Present Invention

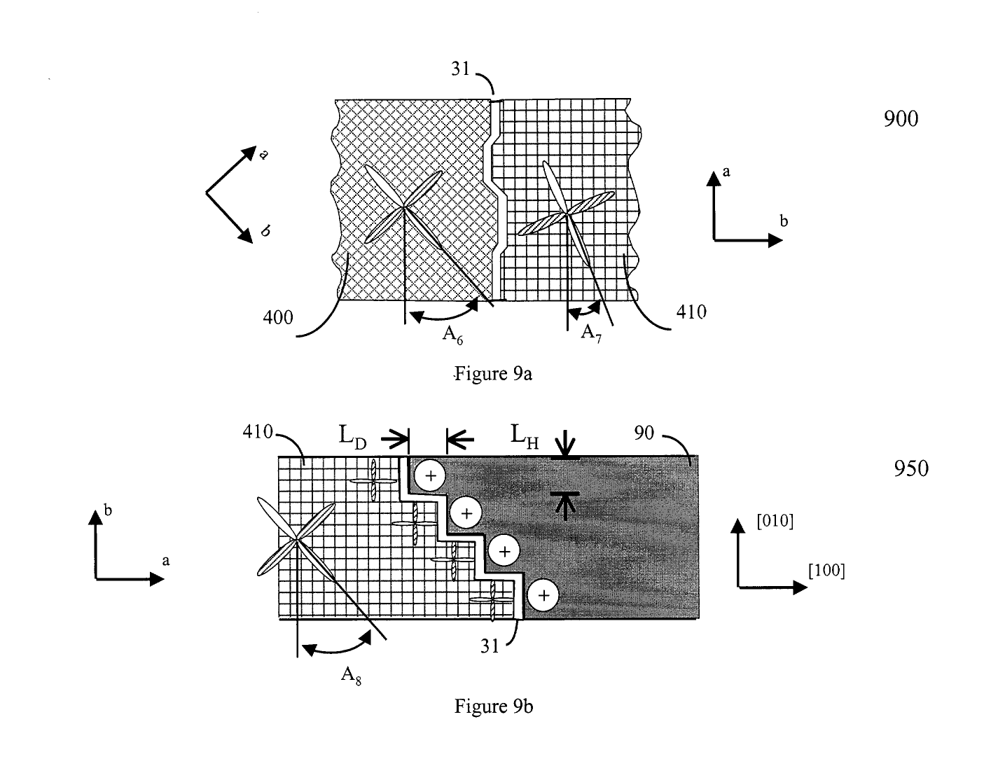

FIGS. 9a and 9b show plan views of two structures 900 and 950 incorporating multifaceted Josephson junctions. In some embodiments, structure 900 (FIG. 9a) is patterned by lithography and ion etching in order to form a Josephson junction 31 that separates superconductors 400 and 410. Josephson junction 31 includes the facets found in the grain boundary in the substrate 100. Structure 900 is formed on a bi-crystal substrate as described above. The width of junction 31 is wider than the facet width. Thus, undesirable phase differences across the junction are formed, as described above. The reference lobe of the order parameter of superconductor 400 makes an angle A₆ with the principal direction of Josephson junction 31. The reference lobe of the order parameter of superconductor 410 makes an angle A₇ with Josephson junction 31. The difference in these angles across junction 31 depends on the angle of junction 31 and this affects the phase of junction 31. Oxygen doping, as described above in reference to FIG. 10a, can enhance the current capacity across junction 31.

Structure 950 (FIG. 9b) includes two different types of superconductors layers (410 and 90) which are interrupted by a normal metal 32. Superconductor 90 is a conventional (e.g., s-wave) superconductor and superconductor 410 is an unconventional superconductor (e.g., a superconductor such as YBCO with time reversal symmetry breaking properties). Thus structure 950 is an SND junction. Superconductor 410 is deposited as described above and then ion etched in order to form a vertical (FIG. 5) or angled (FIG. 6) Josephson junction. Normal metal 32 is placed adjacent to superconductor 410, for example, through the use of a mask. An s-wave type material 90 is deposited next to the normal metal 32. An insulating layer may be deposited on layers 90 and 410 to separate layers 90 and 410. Deposition of an insulating layer may precede the deposition of layer 90 and is particularly useful in creating ramp type junctions, such as the junction shown in FIG. 9b.

The junction shown in structure 950 (FIG. 9b) has artificial facets. Junction 31 is patterned with step-like features, each characterized by two independent lengths L_{H} and L_{D}. An artificially faceted junction may also have steps of varying dimension. Further, the steps need not form a staircase pattern. Any contiguous collection of facets along the edge of superconductor 410 and superconductor 90 may be used. The phase difference across junction 31 is different from a phase difference that would be present if junction 31 were not artificially faceted. The local order parameters are pictured at the junction. Superconductor 410 has the characteristic lobes of a material that has d-wave pairing, but any anisotropy in momentum space will yield an equivalent effect. Material 90 has a spherical (s-wave) order parameter. Here, Josephson junction 31 comprises a normal (e.g. non-superconducting) material. It is clear that traversing Josephson junction material 31 in the [010] direction leads to a different coupling than traversing in the [100] direction. There are more traversals in the [100] direction. In some embodiments of the invention, oxygen doping of such a structure as described above increases the critical current and alters the effective phase difference of the device in a controlled manner.

### Apparatus Manufactured Using the Methods of the Present Invention

The present invention further provides devices that include a submicron grain boundary Josephson junction (e.g. a junction having a width of less than one micron) manufactured in accordance with the present invention. Such devices include superconducting quantum interference devices (SQUIDs), radiation detectors and spectrometers, three-terminal devices, superconducting logic circuits, and research devices. For a review of such devices, see Hilgenkamp and Mannhart, 2002, Reviews of Modem Physics 74, 485-544, which is incorporated herein by reference in its entirety.

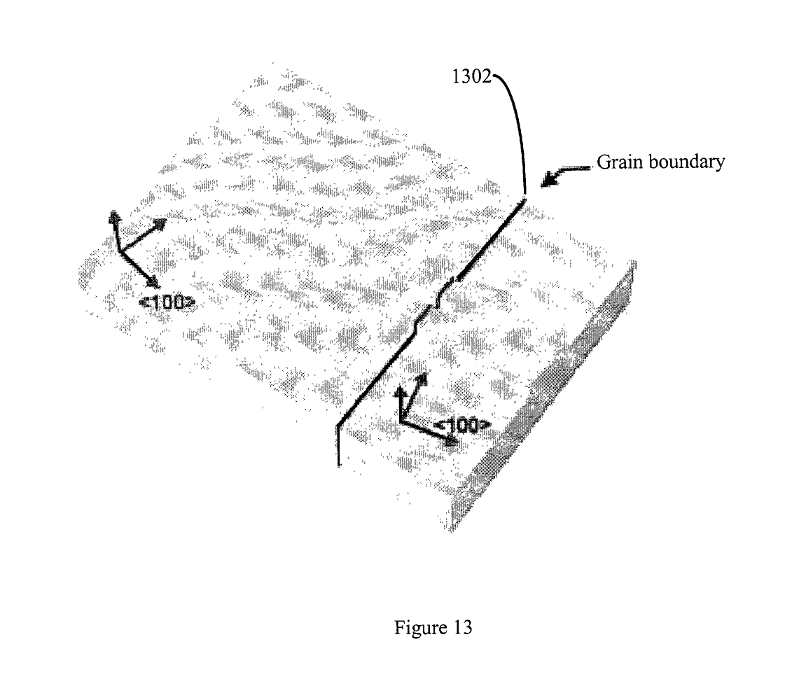

SQUIDS. A configuration of a SQUID in accordance with the prior art is shown in FIG. 13. Specifically, FIG. 13 illustrates a bicrystal de SQUID that includes a Josephson junction 1302 at the grain boundary. By using modulation techniques and appropriate flux-coupling structures, one can operate SQUIDs as highly sensitive sensors for all quantities that can be transduced to a change of magnetic flux, such as magnetic fields, electrical currents, voltages, and position. The methods of the present invention can be used to make improved SQUIDs by reducing the width of the Josephson junctions in such devices in order to avoid the detrimental affects of crystal defects and grain faceting, while at the same time providing a useful critical current.

Radiation Detectors and Spectrometers. The potentially fast response and high output impedance of high-Tc Josephson junctions, both resulting from large I_{c}Rₙ products, have motivated interest in using these junctions as detectors for high-frequency radiation, for example, in telecommunications or in high-frequency spectrometers. One example of a high-frequency spectrometer is a Hilbert transform spectrometer operating from 60 GHz to 2.25 THz. See, for example, Diven et al., 2001, IEEE Trans. Appl. Supercond. 11, 582-585, which is incorporated herein by reference in its entirety. The methods of the present invention can be used to make improved radiation detectors and spectrometers by reducing the width of the Josephson junctions in such devices in order to avoid the detrimental affects of crystal defects and grain faceting, while at the same time providing a useful critical current.

Three-terminal devices. Three-terminal devices that include grain boundaries include Josephson field-effect transistors (JoFET's). In JoFET's, the sensitivity of grain boundaries to applied electric fields is exploited. See, for example, Moore, 1989, in Proceedings of the 2^{nd} Workshop on High Temperature Superconducting Electron Devices, Shikabe, Japan (Research and Development Association for the Future Electron Devices, Whistler, B. C.) p. 281; and Chen et al., 1991, IEEE Trans. Appl. Supercond. 1, 102-107, which are hereby incorporated by reference in their entirety. Further, studies on JoFET's have been reported by Haensel et al., 1997, IEEE Trans. Appl. Supercond 7, 2296-2299, and Windt et al., 1999, Appl. Phys. Lett. 74, 1027-1029, which are hereby incorporated by reference in their entirety. Another three-terminal device that can be manufactured in accordance with the methods of the present invention is a vortex-flow device. Vortex-flow devices are based on the controlled motion of magnetic-flux quanta through superconducting drain-source channels. In these devices, it has turned out to be advantageous to incorporate Josephson junctions to enhance gain, speed, and output impedance. See, for example, Nguyen et al, 1999, IEEE Trans. Appl. Supercond. 9, 3945-3948, and Tavares et al., 1999, IEEE Trans. Appl. Supercond 9, 3941-3944, which are hereby incorporated by reference. In summary, three-terminal structures are used to explore the basic physics of high T_{c} superconductivity and have led to various developments in materials science. The methods of the present invention can be used to make improved three-terminal devices by reducing the width of the Josephson junctions in such devices in order to avoid the detrimental affects of crystal defects and grain faceting, while at the same time providing a useful critical current.

Superconducting logic circuits. Josephson junctions can be switched at subpicosecond speeds, offering the prospect of electronic devices operating at frequencies not attainable with semiconductor circuitry. Based on the (rapid) single-flux-quantum (RSFQ) architecture, logic circuits are being developed with projected operation speeds exceeding 1 THz. The high speeds are combined with low dissipation levels of the RSFQ elements, which are the μW range. Examples of RSFQ circuitry include set-reset registers, RS flipflops, shift register circuits, and analog-to digital converters. See, for example, Hilgenkamp and Mannhart, 2002, Reviews of Modern Physics 74, 485, which is incorporated herein by reference in its entirety. The methods of the present invention can be used to make improved superconducting logic circuits by reducing the width of the Josephson junctions in the devices in order to avoid the detrimental affects of crystal defects and faceting, while at the same time preserving a useful critical current.

Research devices. Grain boundaries are excellent Josephson junctions, which can be fabricated with ease and therefore have been exploited as research devices. Bicrystalline junctions have been found to be particularly fruitful for this purpose, because by choosing the grain-boundary angle, one can freely selected the alignment between the lobes of the wave order parameters of both crystals. Bicrystalline grain boundaries have been used for a variety of basic research experiments, including spectroscopic studies of the cuprates, studies of the temperature-dependent London penetration depth, measurements of the order-paramater symmetry in the high-T_{c} cuprates, and studies of time-reversal symmetry breaking and fractional vortices. For a review, see Hilgenkamp and Mannhart, 2002, Review of Modern Physics 74, 485. The methods of the present invention can be used to make improved research devices by reducing the width of the Josephson junctions in such devices in order to avoid the detrimental affects of crystal defects and faceting, while at the same time preserving a useful critical current.

### Alternate Embodiments

The case of fabricating a grain boundary Josephson junction using YBCO is considered above in order to illustrate the applicability of the present invention to high temperature superconductors. However, those of skill in the art will appreciate that the techniques and structures of the present invention are not limited to YBCO. Rather, the techniques of the present invention are broadly applicable to many classes of materials, particularly superconductors capable of absorbing oxygen. Such superconductors, include, but are not limited to, oxides, copper-containing materials, (e.g. cuprates), and analogous materials like those comprised of ruthenium-oxygen. In the application of the invention to qubits, one of the superconductors may exhibit time reversal symmetry breaking and, equivalently, it can have a non-zero angular momentum state for the Cooper pairs. That is, one of the superconductors on one side of the grain boundary Josephson junction may support Cooper pairs that have a relative orbital angular momentum of one (“p-wave”, i.e., a p-wave material), two (“d-wave”, i.e., a d-wave material), and so forth. The substrate, upon which the superconductor is placed, may be a different material than that of the superconductor.

All references cited herein are incorporated by reference in their entirety and for all purposes to the same extent as if each individual publication or patent or patent application is specifically and individually indicated to be incorporated by reference in its entirety for all purposes. Although the invention has been described with reference to particular embodiments, the description is only examples of the invention's applications and should not be taken as limiting. Various adaptations and combinations of features of the embodiments disclosed are within the scope of the invention as defined by the following claims.

What is claimed is:

1. A method of fabricating a grain boundary Josephson junction on a substrate, the method comprising:
forming a superconducting layer on the substrate;
patterning the superconducting layer thereby forming said grain boundary Josephson junction on said substrate; and
annealing said grain boundary Josephson junction on said substrate.

2. The method of claim 1, wherein said annealing comprises exposing said grain boundary Josephson junction on said substrate to an O₂ plasma.

3. The method of claim 2, wherein said pressure of said O₂ plasma during at least a portion of said exposing is about 0.2 mbar to about 0.6 mbar.

4. The method of claim 2, wherein said grain boundary Josephson junction on said substrate is exposed to said O₂ plasma for at least fifteen minutes.

5. The method of claim 1, the method further comprising heating said grain boundary Josephson junction on said substrate to a temperature of about 80° C. to about 120° C.

6. The method of claim 1, wherein the substrate is a bi-crystal substrate.

7. The method of claim 1 wherein the grain boundary Josephson junction has a width that is smaller than a width of a facet in said substrate.

8. The method of claim 7 wherein the grain boundary Josephson junction has a width between about 10 nm and about 100 nm.

9. The method of claim 1 wherein, forming the superconducting layer on the substrate comprises:
depositing a first superconducting material over a first portion of the substrate; and
depositing a second superconducting material over a second portion of the substrate, wherein said depositing said first superconducting material and said depositing said second superconducting material occurs at the same time.

10. The method of claim 9 wherein
said first portion of the substrate has a first crystallographic orientation and said first superconducting material adopts said first crystallographic orientation; and
said second portion of the substrate has a second crystallographic orientation that is different than said first crystallographic orientation and said second superconducting material adopts said second crystallographic orientation.

11. The method of claim 1, wherein the superconducting layer comprises an unconventional superconducting material.

12. The method of claim 11 wherein the superconducting material layer is a d-wave material.

13. The method of claim 12 wherein the superconducting material is YBa₂CuOₓ.

14. The method of claim 1 wherein said patterning further comprises:
forming a space between a first portion of the superconducting layer and a second portion of the superconducting layer; and
depositing a material in the space, wherein said material is not an unconventional superconductor.

15. The method of claim 14 wherein said material is selected from the group consisting of a non-superconducting metal, a semiconductor, and a dielectric material.

16. The method of claim 1 wherein the substrate is a single crystal substrate having a crystallographic orientation, the method further comprising:
depositing a seed layer on a first portion of the substrate prior to forming the superconducting layer, wherein the seed layer has a crystallographic orientation that differs from the crystallographic orientation of the substrate.

17. The method of claim 1 wherein the superconducting layer is a d-wave superconductor, the method further comprising:
forming an s-wave superconductor layer on the substrate; and
depositing a normal material between the d-wave superconductor and the s-wave superconductor.

18. The method of claim 1 wherein said annealing comprises contacting the grain boundary Josephson junction on said substrate with an O₂ and N₂ gas mixture.

19. The method of claim 18, wherein said O₂ and N₂ gas mixture is formed from a gas mixture that comprises about 500 mbar N₂ to about 1100 mbar N₂ and about 100 mbar O₂ to about 400 mbar O₂.

20. The method of claim 18, wherein said O₂ and N₂ gas mixture is formed from a gas mixture that comprises about 800 mbar of N₂ and about 200 mbar of O₂.

21. The method of claim 18, the method further comprising heating the grain boundary Josephson junction on said substrate to a temperature of about 160° C. to about 240° C.

22. An apparatus including a grain boundary Josephson junction, wherein the grain boundary Josephson junction is manufactured by the method comprising:
forming a superconducting layer on a substrate;
patterning the superconducting layer thereby forming said grain boundary Josephson junction on said substrate; and
annealing said grain boundary Josephson junction on said substrate.

23. The apparatus of claim 22, wherein said annealing comprises exposing said grain boundary Josephson junction on said substrate to an O₂ plasma.

24. The apparatus of claim 23, wherein said pressure of said O₂ plasma during at least a portion of said exposing is about 0.2 mbar to about 0.6 mbar.

25. The apparatus of claim 23, wherein said grain boundary Josephson junction on said substrate is exposed to said O₂ plasma for at least fifteen minutes.

26. The apparatus of claim 22, wherein the substrate is a bi-crystal substrate.

27. The apparatus of claim 22 wherein the grain boundary Josephson junction has a width that is smaller than a width of a facet in said substrate.

28. The apparatus of claim 22 wherein the grain boundary Josephson junction has a width between about 10 nm and about 100 nm.

29. The apparatus of claim 22 wherein, forming a superconducting layer on the substrate comprises:
depositing a first superconducting material over a first portion of the substrate; and
depositing a second superconducting material over a second portion of the substrate, wherein said depositing said first superconducting material and said depositing said second superconducting material occurs at the same time.

30. The apparatus of claim 29 wherein said first portion of the substrate has a first crystallographic orientation and said first superconducting material adopts said first crystallographic orientation; and
said second portion of the substrate has a second crystallographic orientation that is different than said first crystallographic orientation and said second superconducting material adopts said second crystallographic orientation.

31. The apparatus of claim 22, wherein the superconducting layer comprises an unconventional superconducting material.

32. The apparatus of claim 31 wherein the superconducting material is a d-wave material.

33. The apparatus of claim 32 wherein the superconducting material is YBa₂CuOₓ.

34. The apparatus of claim 22 wherein said patterning further comprises:
forming a space between a first portion of the superconducting layer and a second portion of the superconducting layer; and
depositing a material in the space, wherein said material is not an unconventional superconductor.

35. The apparatus of claim 34 wherein said material is selected from the group consisting of a non-superconducting metal, a semiconductor, and a dielectric material.

36. The apparatus of claim 22 wherein the substrate is a single crystal substrate having a crystallographic orientation, the method further comprising:
depositing a seed layer on a first portion of the substrate prior to forming the superconducting layer, wherein the seed layer has a crystallographic orientation that differs from the crystallographic orientation of the substrate.

37. The apparatus of claim 22 wherein said annealing comprises contacting the grain boundary Josephson junction on said substrate with an O₂ and N₂ gas mixture

38. The apparatus of claim 37, wherein said O₂ and N₂ plasma mixture is formed from a gas mixture that comprises about 500 mbar N₂ to about 1100 mbar N₂ and about 100 mbar O₂ to about 400 mbar O₂.

39. The apparatus of claim 37, wherein said apparatus is selected from the group consisting of a superconducting quantum interference device, a radiation detector, a spectrometer, a three-terminal device, and a superconducting logic circuit.
